(19) United States
(12) Patent Application Publication
(10) Pub. No.: US 2017/0162722 A1
(43) Pub. Date: Jun. 8, 2017

(54) PHOTOVOLTAIC STRUCTURES WITH ELECTRODES HAVING VARIABLE WIDTH AND HEIGHT

(71) Applicant: SolarCity Corporation, San Mateo, CA (US)

(72) Inventors: Jianming Fu, Palo Alto, CA (US); Jiunn Benjamin Heng, Los Altos Hills, CA (US); Chunguang Xiao, Fremont, CA (US); Yunlai Yuan, Hangzhou (CN)

(73) Assignee: SolarCity Corporation, San Mateo, CA (US)

(21) Appl. No.: 14/962,451

(22) Filed: Dec. 8, 2015

(51) Int. Cl. H01L 31/02; H01L 31/18; H01L 31/0224

(52) U.S. Cl. CPC H01L 31/0201; H01L 31/022466; H01L 31/1884

(57) ABSTRACT

A method of fabricating a solar cell is described. The solar cell can include a photovoltaic structure and a metallic grid on the photovoltaic structure. The metallic grid can include one or more electroplated metal layers, a busbar, and a plurality of finger lines connected to the busbar, where one or more finger lines have variable widths.

### CROSS-REFERENCE TO OTHER APPLICATIONS

This is related to U.S. patent application Ser. No. 14/045,163, Attorney Docket Number P63-1NUS, entitled “PHOTOVOLTAIC DEVICES WITH ELECTROPLATED METAL GRIDS,” filed Oct. 3, 2013; U.S. patent application Ser. No. 13/220,532, Attorney Docket Number P59-1NUS, entitled “SOLAR CELL WITH ELECTROPLATED METAL GRID,” filed Aug. 29, 2011; and U.S. patent application Ser. No. 14/563,867, Attorney Docket Number P67-3NUS, entitled “HIGH EFFICIENCY SOLAR PANEL,” filed Dec. 8, 2014; the disclosures of which are incorporated herein by reference in their entirety for all purposes.

### FIELD OF THE INVENTION

This disclosure is generally related to solar cell design. More specifically, this disclosure is related to solar cells that include a metal grid fabricated using an electroplating technique.

### DEFINITIONS

A “photovoltaic structure,” refers to a device capable of converting light to electricity. A photovoltaic structure can include a number of semiconductors or other types of materials.

A “solar cell” or “cell” is a type of photovoltaic (PV) structure capable of converting light into electricity. A solar cell may have various sizes and shapes, and may be created from a variety of materials. A solar cell may be a PV structure fabricated on a semiconductor (e.g., silicon) wafer or substrate, or one or more thin films fabricated on a substrate (e.g., glass, plastic, metal, or any other material capable of supporting the photovoltaic structure).

A “finger line,” “finger electrode,” “finger strip,” or “finger” refers to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a PV structure for aggregating current collected by two or more finger lines. A busbar is usually wider than a finger line, and can be deposited or otherwise positioned anywhere on or within the photovoltaic structure. A single photovoltaic structure may have one or more busbars.

A “metal grid,” “metallic gird,” or “grid” is a collection of finger lines and one or more busbars. The metal grid fabrication process typically includes depositing or otherwise positioning a layer of metallic material on the photovoltaic structure using various techniques.

A “solar cell strip,” “photovoltaic strip,” or “strip” is a portion or segment of a PV structure, such as a solar cell. A PV structure may be divided into a number of strips. A strip may have any shape and any size. The width and length of a strip may be the same or different from each other. Strips may be formed by further dividing a previously divided strip.

A “cascade” is a physical arrangement of solar cells or strips that are electrically coupled via electrodes on or near their edges. There are many ways to physically connect adjacent photovoltaic structures. One way is to physically overlap them at or near the edges (e.g., one edge on the positive side and another edge on the negative side) of adjacent structures. This overlapping process is sometimes referred to as “shingling.” Two or more cascading photovoltaic structures or strips can be referred to as a “cascaded string,” or more simply as a string.

### BACKGROUND

An important metric in determining a solar cell's quality is its energy conversion efficiency. To improve a solar cell's efficiency, it is desirable to reduce the metal grid resistance, which typically dominates the overall series resistance of the solar cell. Therefore, it is common to use silver, a metal with low resistivity, to make the metal grid of a solar cell.

FIG. 1 shows an exemplary homojunction solar cell using crystalline silicon (c-Si). Solar cell 100 includes front-side silver (Ag) metal grid 102, anti-reflection layer 104, emitter layer 106, substrate 108, and aluminum (Al) back-side electrode 110. Arrows in FIG. 1 indicate incident sunlight.

In exemplary solar cell 100, carriers can be collected by front-side Ag metal grid 102. To form Ag metal grid 102, conventional methods involve printing Ag paste (which often includes Ag particle, organic binder, and glass frit) onto the wafers and then firing the Ag paste at a temperature between 700° C. and 800° C. The high-temperature firing of the Ag paste can ensure good contact between Ag and silicon (Si), and can lower the resistivity of the Ag lines. Even though this conventional method uses silver paste and firing technique to reduce the metal grid resistance, the resistivity of the fired Ag paste can typically be between 5×10⁻⁶ and 8×10⁻⁶ ohm-cm, which is much higher than the resistivity of bulk silver.

In addition to the high series resistance, the electrode grid obtained by screen-printing Ag paste also has other disadvantages, such as higher material cost and limited metallic line height. As the price of silver rises, the material cost of the silver electrode could exceed half of the cost for manufacturing solar cells. Furthermore, the height of the Ag lines within the metal grid is limited by the printing methods. A single run of printing can produce Ag lines with a height less than 25 microns. Although multiple printing runs can produce lines with increased height, it also can increase the metallic line width, which can be undesirable for high-efficiency solar cells.

There has been a growing usage of copper, instead of silver, as an electrode material to increase sustainability and reduce the production cost of solar cells. However, using copper can introduce additional challenges to the manufacturing process of the solar cells, such as poor adhesion to silicon substrate, diffusion into the silicon wafer, which can create re-combination currents for carriers, and additional manufacturing steps.

Another solution is to electroplate a nickel (Ni)/Cu/Tin (Sn) metal stack directly on the Si emitter layer of the photovoltaic structure. This method can produce a copper plated metal grid with lower resistance typically between 2×10⁻⁶ and 3×10⁻⁶ ohm-cm. However, the adhesion of Ni to Si can be less than ideal, and stress from the metal stack may result in peeling of the metal grid, breakage, of at least some portion of, and/or warpage of the substrate due to thicker metal stack. Therefore, an improved metal grid design and fabrication process is desired to manufacture reliable, low cost, and high efficiency solar cells.

### SUMMARY

One embodiment of the present invention provides a solar cell. The solar cell can include a photovoltaic structure and a metallic grid on the photovoltaic structure. The metallic grid can also include one or more electroplated metal layers. The metallic grid also includes a busbar, one or more finger lines connected to the busbar, where one or more finger lines have a variable width.

In some embodiments, the variable width of the one or more finger lines varies in a linear manner.

In some embodiments, the variable width of the one or more finger lines varies in a non-linear manner.

In some embodiments, the one or more finger lines with variable width includes multiple connected segments with fixed widths.

In some embodiments, more than one segment of the one or more finger lines vary in width.

In some embodiments, an intersection between the busbar and the one or more finger lines is rounded or chamfered.

In some embodiments, intersections between different segments of one or more finger lines are rounded or chamfered.

In some embodiments, the one or more finger lines with a variable width has a concave shape, convex shape, or a combination thereof.

In some embodiments, the metallic grid further includes a metal adhesive layer between the electroplated metal layer and the photovoltaic structure. The metal adhesive layer includes one or more of Cu, Al, Co, W, Cr, Mo, Ni, Ti, Ta, titanium nitride (TiNₓ), titanium tungsten (TiWₓ), titanium silicide (TiSiₓ), titanium silicon nitride (TiSiN), tantalum nitride (TaNₓ), tantalum silicon nitride (TaSiNₓ), nickel vanadium (NiV), tungsten nitride (WNₓ), and their combinations.

In some embodiments of the present invention provides a solar cell. The solar cell can include a photovoltaic structure and a metallic grid on the photovoltaic structure. The metallic grid can also include one or more electroplated metal layers. The metallic grid also includes a busbar, one or more finger lines connected to the busbar, where one or more finger lines have a variable height.

In some embodiments, the variable height of the one or more finger lines varies in a linear manner.

In some embodiments, the variable height of the one or more finger lines varies in a non-linear manner.

In some embodiments, the one or more finger lines with variable height includes multiple connected segments with fixed heights.

In some embodiments, more than one segment of the one or more finger lines vary in width.

In some embodiments, the photovoltaic structure includes a transparent conducting oxide (TCO) layer, and the metal adhesive layer is in direct contact with the TCO layer.

In some embodiments, the electroplated metal layers include one or more of a Cu layer, an Ag layer, and a Sn layer.

In some embodiments, the metallic grid further includes a metal seed layer between the electroplated metal layer and photovoltaic structure.

In some embodiments, the metal seed layer is formed using a physical vapor deposition (PVD) technique, including evaporation or sputtering deposition.

In some embodiments, a predetermined edge portion of the respective finger line has a width that is larger than a width of a center portion of the respective finger line.

In some embodiments, the photovoltaic structure includes a base layer, and an emitter layer above the base layer. The emitter layer includes regions diffused with dopants located within the base layer, a poly silicon layer diffused with dopants situated above the base layer, or a doped amorphous silicon (a-Si) layer above the base layer.

In some embodiments, a back junction solar cell is provided, which includes a base layer, a quantum-tunneling-barrier (QTB) layer situated below the base layer facing away from incident light, an emitter layer situated below the QTB layer, a front surface field (FSF) layer situated above the base layer, a front-side electrode situated above the FSF layer, and a back-side electrode situated below the emitter layer.

### BRIEF DESCRIPTION OF THE FIGURES

FIG. 1 shows an exemplary solar cell.

FIG. 2A shows an exemplary electroplated metallic grid with fixed width finger line on the front surface of a solar cell.

FIG. 2B shows exemplary electroplated metallic grid with fixed width finger line on the back surface of a solar cell.

FIG. 3A shows a detailed view of an exemplary electroplated metallic grid with a finger line having a linear variable width segment on a surface of a solar cell, in accordance with an embodiment of the present invention.

FIG. 3B shows a cross section view of an exemplary electroplated metallic grid with a finger line having a linear variable height segment on a surface of a solar cell, in accordance with an embodiment of the present invention.

FIG. 4A shows a detailed view of an exemplary electroplated metallic grid with a finger line having multiple segments with variable widths on a surface of a solar cell, in accordance with an embodiment of the present invention.

FIG. 4B shows a cross section view of an exemplary electroplated metallic grid with a finger line having multiple segments with variable heights on a surface of a solar cell, in accordance with an embodiment of the present invention.

FIG. 5A shows a detailed view of an exemplary electroplated metallic grid with a finger line having multiple segments with variable widths from one end to the opposite end on a surface of a solar cell, in accordance with an embodiment of the present invention.

FIG. 5B shows a cross section view of an exemplary electroplated metallic grid with a finger line having multiple segments with variable widths from one end to the opposite end on a surface of a solar cell, in accordance with an embodiment of the present invention.

FIG. 6 shows an exemplary electroplated metallic grid with a finger line having multiple fixed width segments on a surface of a solar cell, in accordance with an embodiment of the present invention.

FIG. 7 shows an exemplary electroplated metallic grid with a finger line having a non-linear variable width segment on a surface of a solar cell, in accordance with an embodiment of the present invention.

FIG. 8 shows an exemplary electroplated metallic grid with a finger line having multiple non-linear variable width segments on a surface of a solar cell, in accordance with an embodiment of the present invention.

FIG. 9 shows an exemplary electroplated metallic grid with a variable width finger line having rounded corners on a surface of a solar cell, in accordance with an embodiment of the present invention.

FIG. 10 shows an exemplary electroplated metallic grid with variable width finger lines on a surface of a solar cell, in accordance with an embodiment of the present invention.

FIG. 11 shows an exemplary electroplated metallic grid with variable width finger lines on a surface of a solar cell, in accordance with an embodiment of the present invention.

FIG. 12 shows an exemplary process of fabricating a solar cell in multiple steps in accordance with an embodiment of the present invention.

FIG. 13 shows an exemplary process of fabricating a back junction solar cell with tunneling oxide, in accordance with an embodiment of the present invention.

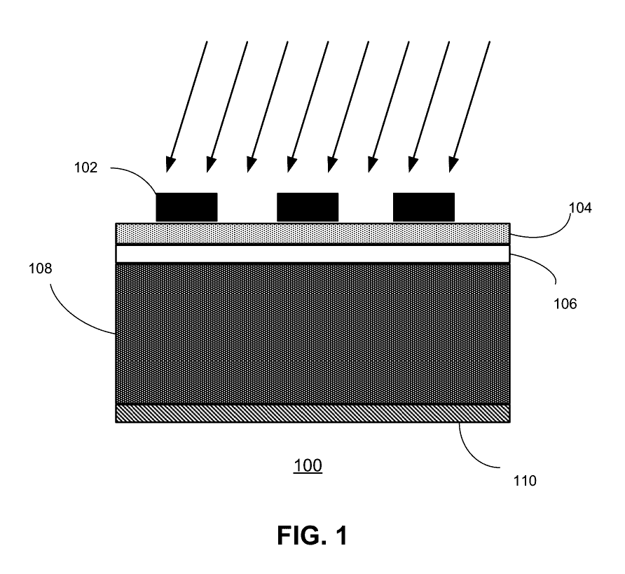

In the figures, like reference numerals refer to the same figure elements.

### DETAILED DESCRIPTION

This description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the invention is not limited to the embodiments shown, but is to be accorded the widest scope consistent with the principles and features disclosed herein.

### Overview

Embodiments of the present invention solve the problem of providing a robust and cost-effective electrode for a PV structure by using a special electrode design that can reduce abrupt changes in line width of the metallic grid. As a result, an electroplated metallic grid can have more gradual changes in its stack height, which can reduce the likelihood of the metallic grid peeling away from the PV structure.

To increase reliability and efficiency of a photovoltaic structure at least a portion of one or more of finger lines within the metallic grid can have variable widths. The joint between a busbar and a finger line can be designed to form a gradual transition, to allow the stack height of the busbar to transition gradually to the stack height of the finger line, which can be significantly narrower than the busbar.

On a bifacial PV structure, the back-side electrode metallic grid can be formed using a similar method that may be used to form the front-side electrode metallic grid. Additionally, the metallic grid may be formed by screen-printing, electroplating, or aerosol-jet printing.

### Solar Panel Based on Cascaded Strips

Conventional solar panels generally include a single string of serially connected standard-size, undivided photovoltaic structures. As described in U.S. patent application Ser. No. 14/563,867 (incorporated by reference), it can be more desirable to have multiple (such as 3) strings, each string including cascaded strips, and connect these strings in parallel. Such a multiple-parallel-string panel configuration can provide the same output voltage with a reduced internal resistance. In general, a cell can be divided into n strips, and a panel can contain n strings, each string having the same number of strips as the number of regular photovoltaic structures in a conventional single-string panel. Such a configuration can ensure that each string outputs approximately the same voltage as a conventional panel. The n strings can then be connected in parallel to form a panel. As a result, the panel's voltage output can be the same as that of the conventional single-string panel, while the panel's total internal resistance can be 1/n of the resistance of a string (note that the total resistance of a string made of a number of strips can be a fraction of the total resistance of a string made of the same number of undivided cells). Therefore, in general, the greater n is, the lower the total internal resistance of the panel can be, and the more power one can extract from the panel. However, a tradeoff is that as n increases, the number of connections required to inter-connect the strings also increases, which can increase the amount of contact resistance. Also, the greater n is, the more strips a single cell may need to be divided into, which may increase the associated production cost and decrease overall reliability due to the larger number of strips used in a single panel.

Another consideration in determining n is the contact resistance between the electrode and the photovoltaic structure on which the electrode is formed. The greater this contact resistance is, the greater n might need to be to reduce effectively the panel's overall internal resistance. Hence, for a particular type of electrode, different values of n might be needed to attain sufficient benefit in reduced total panel internal resistance to offset the increased production cost and reduced reliability. For example, conventional silver-paste or aluminum based electrode may require n to be greater than 4, because the process of screen printing and annealing silver paste on a cell does not produce ideal resistance between the electrode and underlying photovoltaic structure.

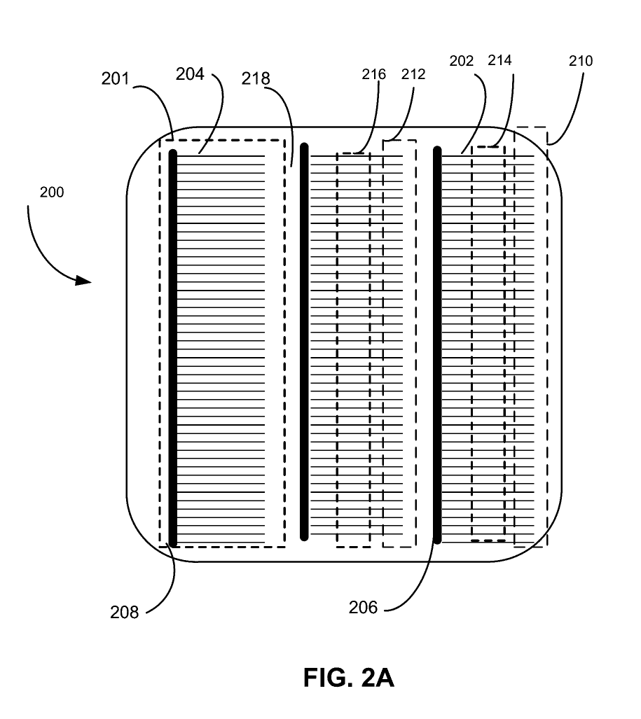

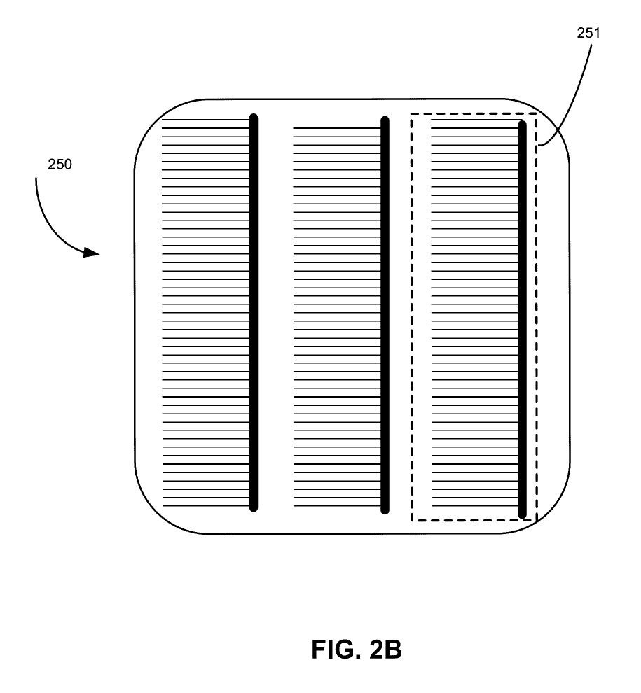

FIG. 2A shows an exemplary grid pattern on a photovoltaic structure, according to one embodiment of the present invention. In the example shown in FIG. 2A, grid 200 includes three sub-grids, such as sub-grid 201. This three sub-grid configuration allows the photovoltaic structure to be divided into three strips. To enable cascading, each sub-grid can have an edge busbar. In the example shown in FIG. 2A, each sub-grid can include an edge busbar (“edge” here refers to the edge of a respective strip) along the longer edge of the corresponding strip and a plurality of finger lines running substantially parallel to the shorter edge of the strip. For example, sub-grid 201 can include edge busbar 208, and a plurality of finger lines, such as finger line 204. To facilitate a subsequent scribe-and-cleave process, a predefined blank space (i.e., space not covered by electrodes) can be placed between the adjacent sub-grids. In some embodiments, the width of the blank space, such as blank space 218, can be between 0.1 mm and 5 mm, preferably between 0.5 mm and 2 mm. There is a tradeoff between a wider space that leads to more tolerant scribing operation and a narrower space that leads to more effective current collection. In a further embodiment, the width of such a blank space can be approximately 1 mm.

FIG. 2B shows an exemplary grid pattern on the back surface of a photovoltaic structure, according to one embodiment of the invention. In the example shown in FIG. 2B, back grid 250 includes three sub-grids, such as sub-grid 251. To enable cascaded and bifacial operation, the back sub-grid can correspond to the front-side sub-grid. More specifically, the back edge busbar can be located at an opposite edge with respect to the corresponding front-side edge busbar. In the examples shown in FIGS. 2A and 2B, the front and back sub-grids have similar patterns except that the front and back edge busbars are located adjacent to opposite edges of the strip. In addition, locations of the blank spaces in back metallic grid 218 can correspond to locations of the blank spaces in front metallic grid 200, such that the grid lines do not interfere with the subsequent scribe-and-cleave process. In practice, the finger line patterns on the front- and back-side of the photovoltaic structure may be the same or different.

### Electroplated Metallic Grid

Electroplated metallic grids have shown lower resistance than printed Ag and Al grids. However, to prevent metal (e.g. copper) diffusion in silicon, which results in re-combination centers, a transparent conductive oxide (TCO) can be used. The adhesion might be less than ideal between the electroplated metal lines of the grid and the underlying transparent conducting oxide (TCO) layers. Even with introduction of an adhesion layer, as the thickness of the electroplated metal lines varies in different regions due to different line widths, peeling can still occur due to stress and mismatching thermal expansions. The peeling of metal lines can be a result of stress buildup at the interface between the electroplated metal and the underlying structures, either the TCO layer or the semiconductor structure. The difference in thermal expansion coefficients between the metal and the TCO or silicon and the thermal cycling of the environment, where the photovoltaic structures are often placed, leads to such stress. If the amount of the stress exceeds the adhesion strength provided by the adhesion layer, the bonding between the metal and the underlying layers could break.

It is generally desirable to design metallic grid lines with a high height-to-width aspect ratio to reduce electrode resistance and shading. However, the height-to-width aspect ratio of finger lines is often limited by their footprint and the fabrication technology used for forming the metallic grid. Conventional printing technologies, such as screen-printing, often result in metal lines with relatively low height-to-width aspect ratio. Electroplating technologies can produce metal lines with greater height-to-width aspect ratio. However, the narrow finger lines and wider busbars may result in different heights in the deposited metal. Consequently, the finger lines and busbars may experience different levels of stress caused by thermal expansion coefficient mismatch with the underlying PV structure. The electrodes may eventually experience peeling when placed in an environment with a changing temperature. As previously mentioned, the difference in thermal expansion coefficients between the metal and the PV structure (e.g., the TCO layer), and the changing temperatures can lead to stress buildup and eventually break the adhesion between the metal and the underlying layers. Even though the breakage may happen at a single location, the good malleability of the plated metal, such as plated Cu, can lead to peeling of the entire metal line and/or breakage at the location where grid line joins a busbar. In addition, in some cases the stress buildup can result in warpage and/or breakage of a photovoltaic structure.

Note that the amount of stress is generally related to the height-to-width aspect ratio of the metal lines; the larger the aspect ratio, the larger the stress. Hence, assuming the metal lines have a uniform width, which can be well controlled during fabrication, the taller portion of the line can experience greater stress. For most of electroplated metallic grids, more metal generally deposited at the tip of finger lines away from a busbar that could produce finger lines with the thicker tip due to the current crowding effect. In order to compensate for these thicker segments of the finger lines, a variable height finger line can be created to provide a more uniform thickness across the finger line which results in better stress distribution across the finger lines.

When electroplating metallic grid of cascaded strips, metals deposited at the strip edge away from edge busbars could be taller due to the current crowding effect occurring at the edge of the strip near blank spaces. In the example shown in FIGS. 2A and 2B, electroplated metal lines located in strip edge regions, such as regions 210 and 212, might be thicker. As one can see from FIGS. 2A and 2B, conventional metallic grid 200 includes finger lines with uniform width. In order to compensate for thicker regions 210 and 212, a variable width finger line can be created to provide a more uniform thickness for the finger lines. These variable segments of the finger lines can be near regions 210 and 212, where the finger lines might have greater thicknesses and, thus, may experience larger amounts of thermal stress. By introducing a variable width finger line having a variable width in a portion of the finger line, for example in regions 214 and 216, the stress can be evenly distributed throughout the finger line. As a result, there can be fewer locations that experience abrupt stress changes in regions 210 and 212, which can reduce the chance of electrode peeling and/or breakage of photovoltaic structures.

In addition to thermal stress, handling of the devices during fabrication of the solar module, such as storing, tabbing, and stringing, can also lead to peeling in the metallic grid. For example, while the photovoltaic structures are being handled by machines or people, it is possible that finger lines may be pushed from side to side by other objects, such as strip edges of different wafers or metal lines on a wafer stacked above. Coincidentally, the end portions of the finger strips are often the weakest point in terms of resisting external forces.

Hence, to reduce the peeling of the metal lines, it is desirable to distribute the stress more evenly along a metal line to avoid high stress points that may jeopardize the integrity of the electrode. One way to do so is to increase the width of the middle portion of the finger line so that the effect of change in height of the end portion of the finger line can be reduced. The increased line width or footprint of the middle portion of the finger lines means that the collected current is now spread over a larger area and is distributed in a more uniform manner through the finger line, hence mitigating the current crowding effect that is caused by non-uniform current distribution as the thin finger line approaches the intersection with the busbar. However, to avoid shading loss, the increase in line width can be made sufficiently small, for example from a few microns to tens of microns, so that the overall effect can be negligible.

As mentioned above, electroplated metallic grids generally can achieve a higher aspect ratio than conventional methods. Another factor to consider when using an electroplated metallic grid is the loading effect. The loading effect refers to the varying thicknesses at different areas of the electroplated surface due to varying surface areas. For example, an electroplated busbar can have a greater thickness compared with the fine sized finger lines of the metallic grid.

The loading effect seen in an electroplated metallic grid can be thought of as building a pyramid shaped object using metal particles in an electroplating process. The height of the pyramid has a direct relationship with the initial footprint of the pyramid. Therefore, a bigger footprint can result in a higher and more stable pyramid. This is also true for depositing the fine metallic. The wider the line width of the finger lines, the thicker the electroplated finger lines.

As can be seen, the loading effect can result in different heights in the electroplated metallic grid, where the width of the intended metallic grid can partially determine the height of the deposited metallic grid components. For example, a busbar could be much thicker than a finger line as the width of the busbar is typically greater than that of a finger line. The abrupt change in height of metallic lines at or near joints of finger lines and the busbar can cause an abrupt change in physical stress which may affect the reliability of the photovoltaic structure. One way to mitigate such abrupt stress change due to the loading effect is to have a thicker finger line at or near such locations. For example, portions of finger lines close to the busbar can be made thicker in order to create a smoother height transition. In addition, other portions of finger lines can be widened to reduce any abrupt changes in thickness throughout different segments of a finger line. In one embodiment, the middle portion of the finger lines can be widened in addition to or instead of having a wider finger line at or near the intersection of the finger lines and the busbar. This can further provide a gradual increase of height in finger lines causing an even more uniform thickness within a metallic grid. Consequently, wider design of finger lines would translate to a thicker metal deposition at critical stress points resulting in a more reliable photovoltaic structure.

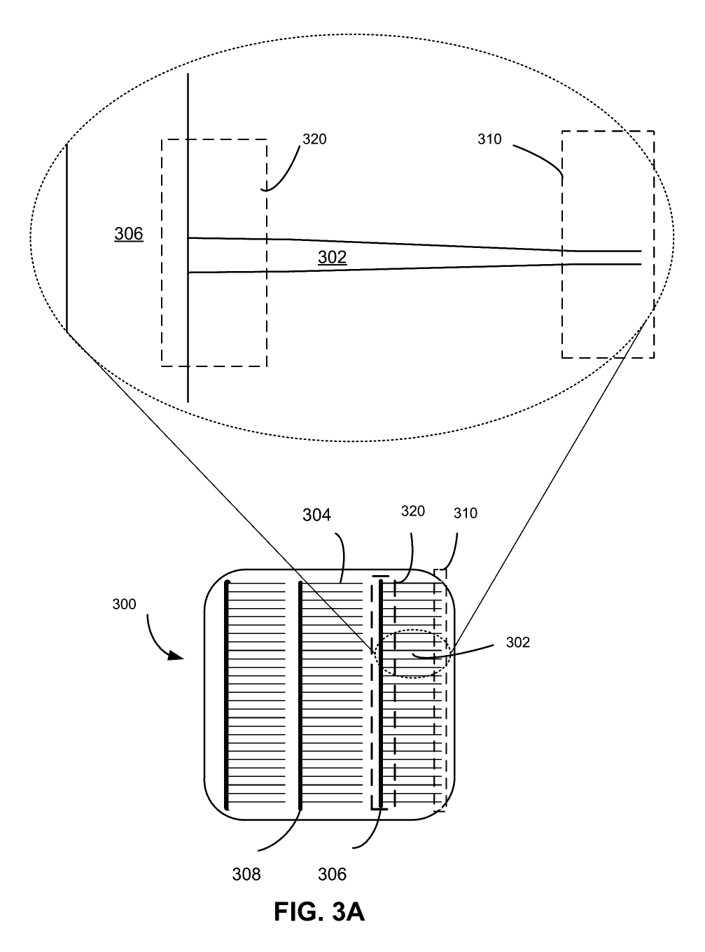

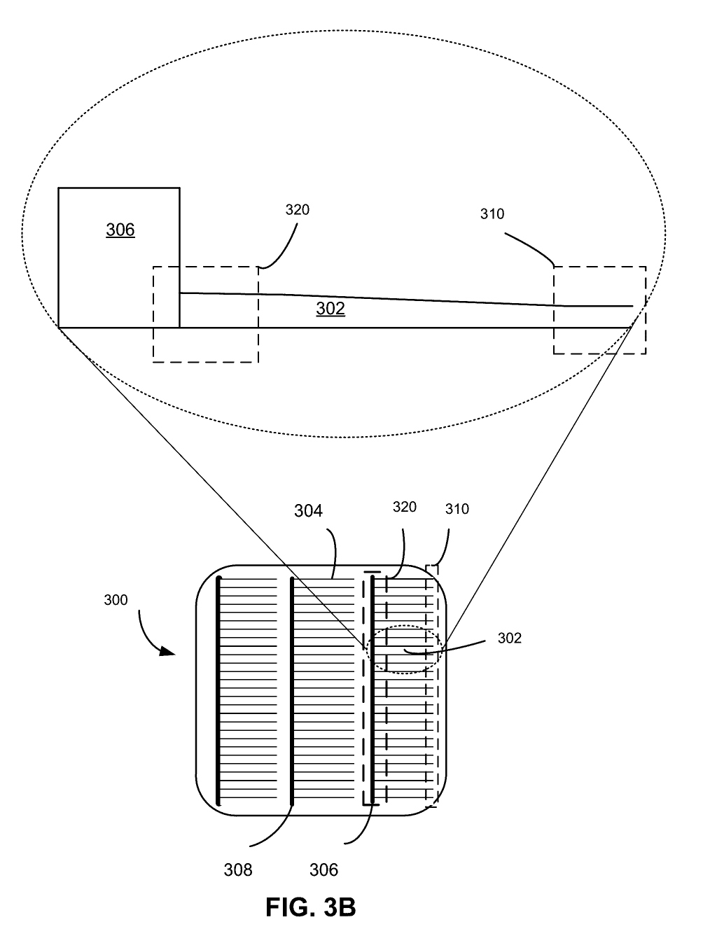

Embodiments of the present invention include enhanced electroplated grid designs that provide a metallic grid that is more resistant to peeling, has more uniform stress distribution, and has smaller overall series resistance. FIGS. 3A and 3B show an exemplary electroplated metallic grid of a photovoltaic structure, according to an embodiment of the present invention. In FIGS. 3A and 3B, metallic grid 300 includes a number of finger lines, such as finger lines 302 and 304, and busbars 306 and 308. However, unlike metallic grid 200 where each finger strip is fabricated with a fixed width, in FIGS. 3A and 3B, one or more finger lines have at least one segment with a variable width. For example, the middle portion of finger line 302 can have a gradual increasing width from one end of a finger line at or near an edge of the of the finger line (e.g., region 310) toward the opposite end of the finger line, at or near the intersection region of finger line and a busbar (e.g., region 320). According to one embodiment, a segment of finger line 302 located in region 320 can be wider than other segments located in region 310 to avoid any abrupt changes near the variable width segment.

Two goals can be simultaneously achieved by having a variable width finger line. The first goal is to mitigate the current crowding effect during electroplating. Thus, increasing the thickness of the metal deposited at other segments of a finger line can create wider current pathways, as shown in FIG. 3B. Compared with the examples shown in FIGS. 2A and 2B, during electroplating where the end portion of finger line patterns experience concentrated current, the variable width of the finger line as shown in FIG. 3A can cause the current originally concentrated at the tips of the finger strips, such as finger lines 302 and 304, to be diverted away through the wider pathway of the rest of the finger line. Consequently, current densities at the tips of the finger strips can be reduced to provide a more equal current concentration across the finger lines. This can create a more uniform height of the deposited metal after the electroplating process, which can lead to smaller additional stress buildup at the tips of the finger strips, such as regions 310, when the ambient temperature changes.

The second goal achieved by implementing the variable width of the finger line is to eliminate the weak spots/abrupt-stress-change points formed at or near the intersection of the finger line and the busbar, for example in region 320, as shown in FIG. 3B. By having a wider finger line in other portions of the finger line, the original abrupt height change of deposited metal can be turned into a smoother transition. Note that, as discussed previously, the abrupt change in height of the metal layer may cause a breakage or warpage of the photovoltaic structure when external forces are applied and/or extreme temperature changes occur at the installation site of the photovoltaic structures. However, in the example shown in FIG. 3B, when external forces are applied and/or extreme temperature changes occur, it is less likely for the end portions of finger strip 302 to break away from the underlying layers or for a photovoltaic structure to warp and/or break since the finger line has a more uniform aspect ratio and weak spots have been eliminated.

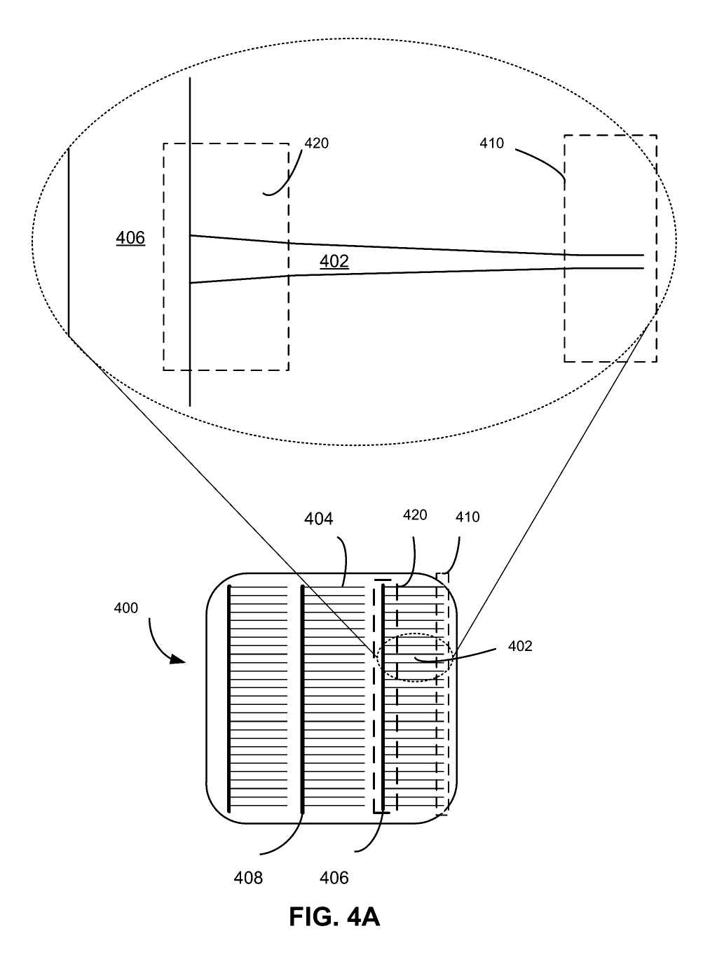

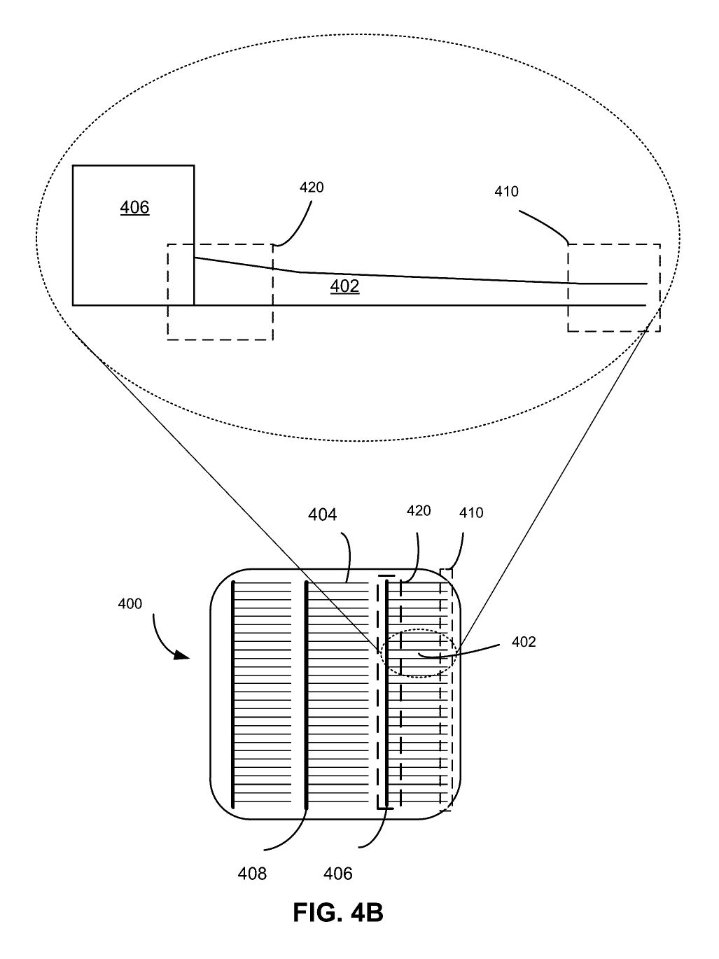

In addition to the example shown in FIGS. 3A and 3B, other grid patterns can also be used to create a more robust electroplated metallic grid using the variable width technique. FIGS. 4A and 4B show an exemplary electroplated metallic grid on the surface of a photovoltaic structure, according to an embodiment of the present invention. Like the example shown in FIGS. 3A-3B, the resulting grid pattern can include a finger line having a variable width, but in at least two distinct segments of the finger line. In the example shown in FIGS. 4A-4B, instead of creating a variable width in one section of the finger line, additional section(s) of the finger line can also have a variable width. For example, region 420 of the finger line can also have a variable width to further assist in creation of the uniform thickness of the metallic grid while reducing the overall series resistance of the photovoltaic structure. By simultaneously increasing thickness uniformity of finger lines and gradual height increase from the finger line to a busbar as shown in FIG. 4B, embodiments of the present invention can effectively reduce the possibility of peeling of the finger lines and wafer breakage and/or warpage thereby providing a more affordable long-term maintenance cost to consumers.

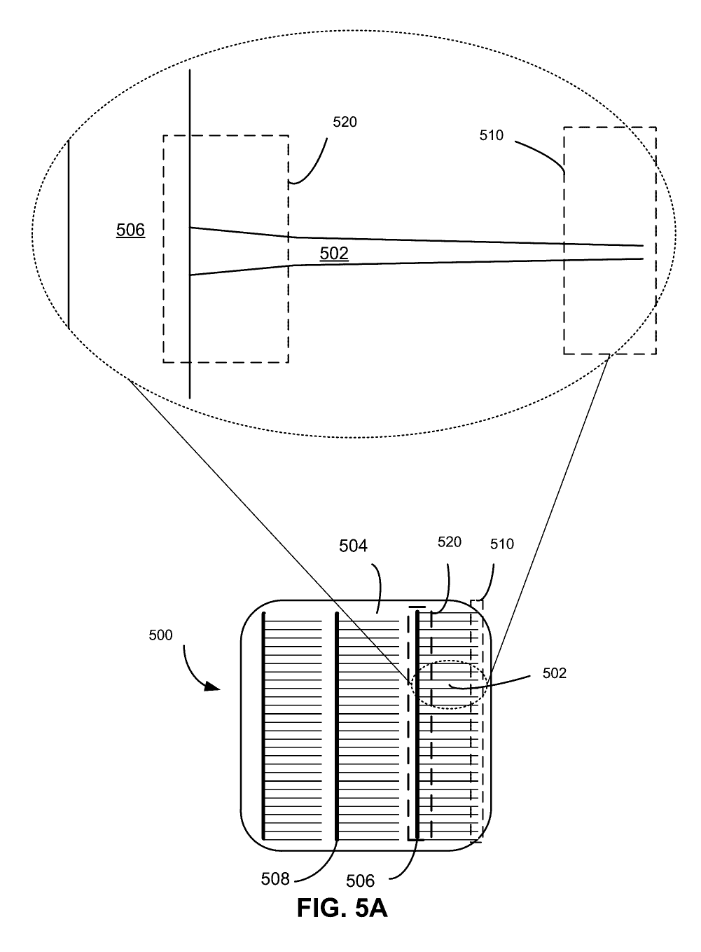

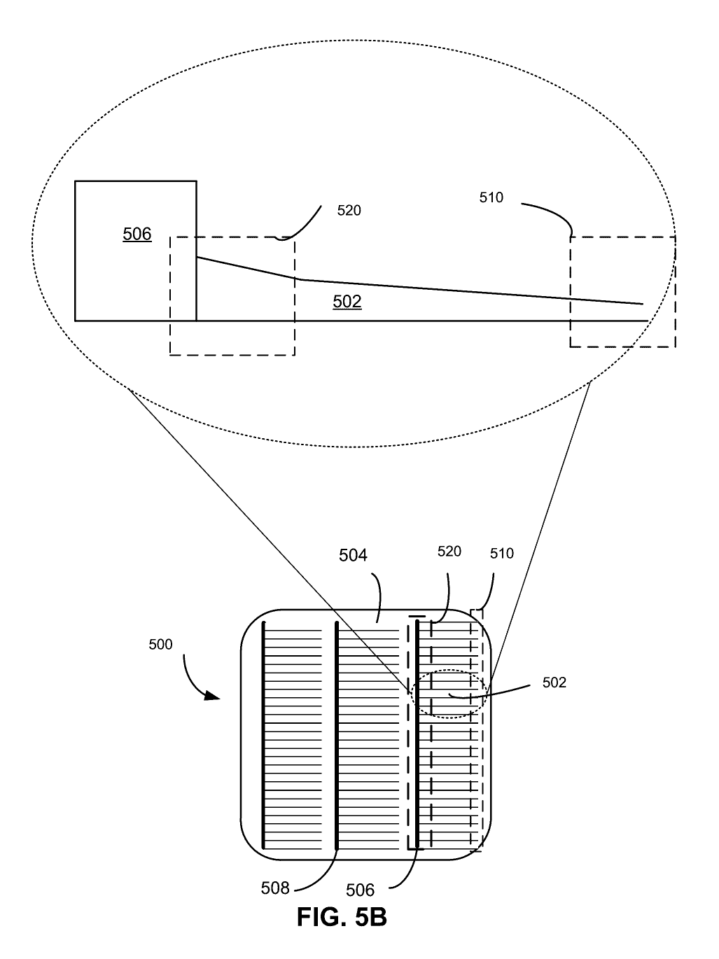

FIGS. 5A-5B show an exemplary electroplated metallic grid placed on a surface of a photovoltaic structure, according to an embodiment of the present invention. Like the example shown in FIGS. 3A-3B, the resulting grid pattern can include a finger line having a variable width. Additional segments of the finger line, however, can also be designed to have variable widths to further mitigate the undesirable effects of electroplating. As shown in FIG. 5B, region 510 of finger line 502 can have a variable width to further assist in creating a more uniform thickness of the metallic grid. A finger line width could be gradually increasing from one end to the opposite end. The example pattern of the metallic grid shown in FIG. 5A can further decrease the overall resistance of the metallic grid and reduce the charge concentration near the edge of each finger line. To reduce the effect of shading loss, the finger line width can vary at different rates along the finger line. For example, the variable width of the finger line can have a lower increase rate toward one end of the finger line close to the strip edge (e.g., region 410) and higher increase rates near the intersection of the finger line and a busbar (e.g., region 420). Using different width increase rates for different segments of a finger line can provide a balance between improved characteristics of the photovoltaic structure and shading loss caused by increased finger line width.

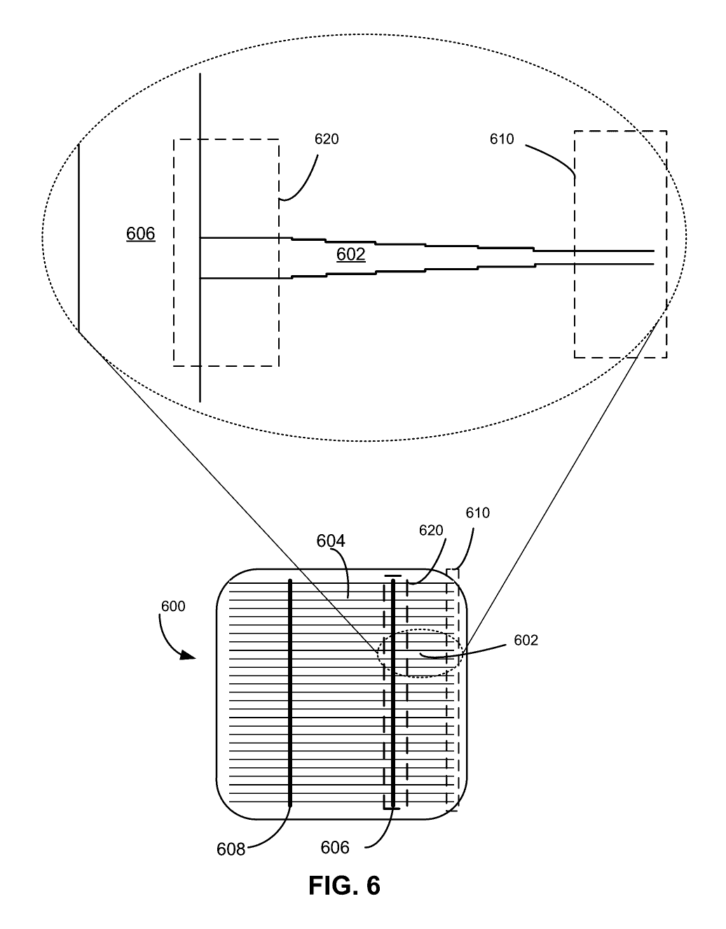

Different metallic grid pattern may be used to implement a variable width finger line. In an embodiment, a specific pattern design can be used for ease of manufacturing while maximizing the surface area and reducing the shading loss in a photovoltaic structure. FIG. 6 shows another exemplary electroplated metallic grid on the surface of a photovoltaic structure, according to an embodiment of the present invention. As shown in FIG. 6, a portion of a variable width segment of a finger line may be divided into multiple smaller segments each having a different fixed width value. This way, variances of the variable width section of the finger line can be better controlled with greater accuracy during fabrication.

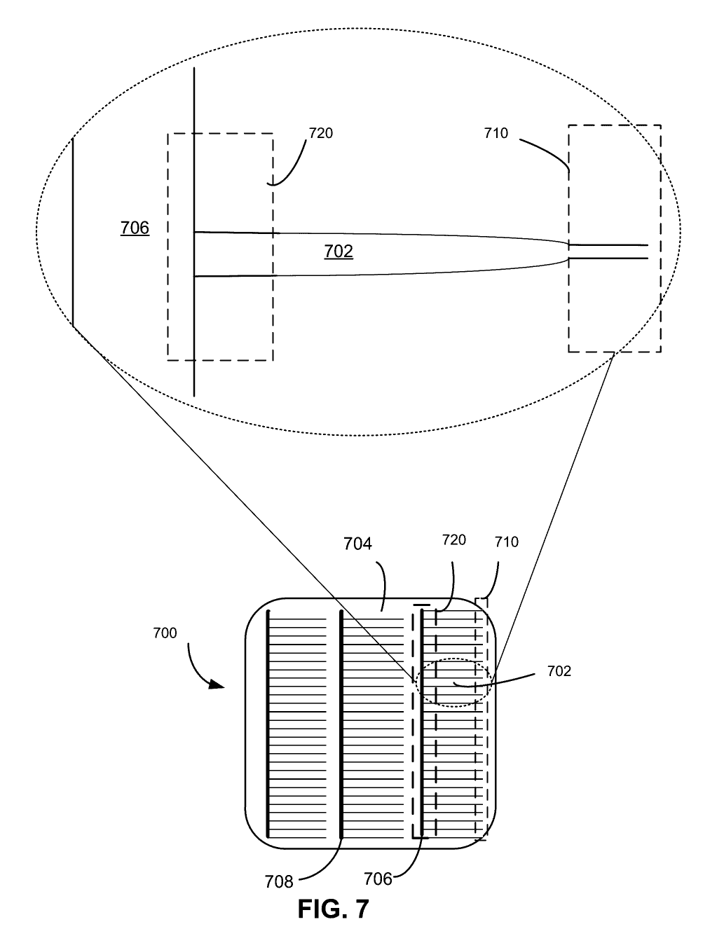

In another embodiment, the variable width segment of a finger line can exhibit a non-linear gradual increase with different patterns including curved lines with different lengths and shapes. Such non-linear gradual increase can provide a smooth transition between electroplated metallic grid elements so that the metallic grid can have more gradual changes in its stack height, which can reduce the likelihood of the metallic grid peeling away from the PV structure. FIG. 7 shows an exemplary electroplated metallic grid of a photovoltaic structure, according to an embodiment of the present invention. As shown in FIG. 7, the variable width segment of the finger line can be designed so that a slight curve can cover the variable width portion of the finger line. The curve covering the variable width segment may have an increasing width from region 710, where the finger line is close to the strips' edge away from busbar 706, for example region 720, to where the finger line intersects with busbar 706. The curve covering the variable width segment of the finger line may have different curvatures. The right curvature can be chosen to provide the smoothest transition between fixed and variable segments of the finger line.

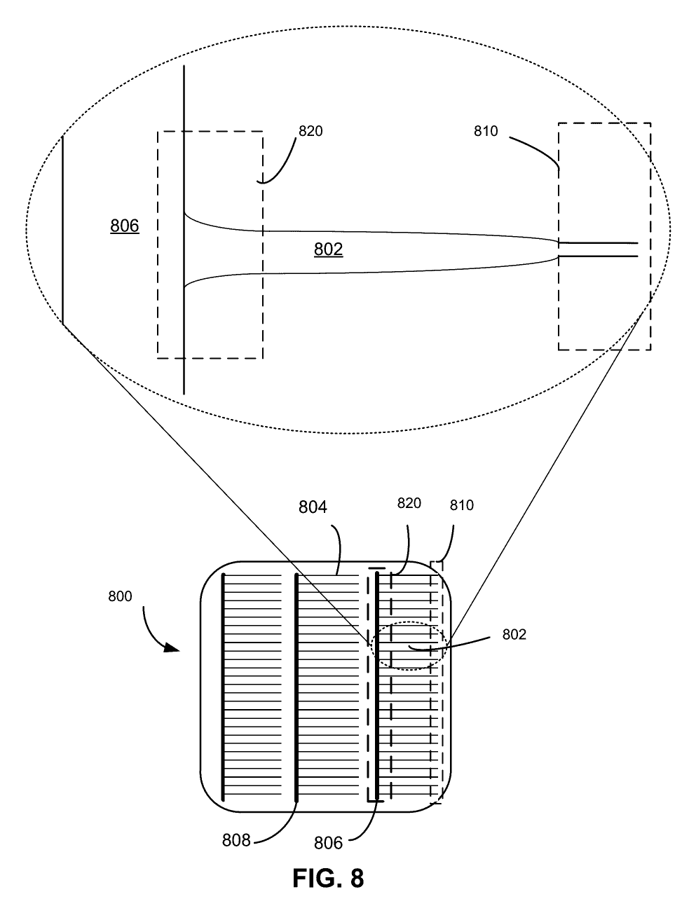

In another embodiment, more than one single segment of the finger line with variable width can be curve-shaped. These curves may have different curvatures and directions (e.g. concave and/or convex curves). FIG. 8 shows an exemplary electroplated metallic grid with a finger line that not only has a curved middle segment in between regions 810 and 820, but also has a curved pattern having a different direction at or near region 820. Hence, smoother transition between the finger lines and busbar can be created.

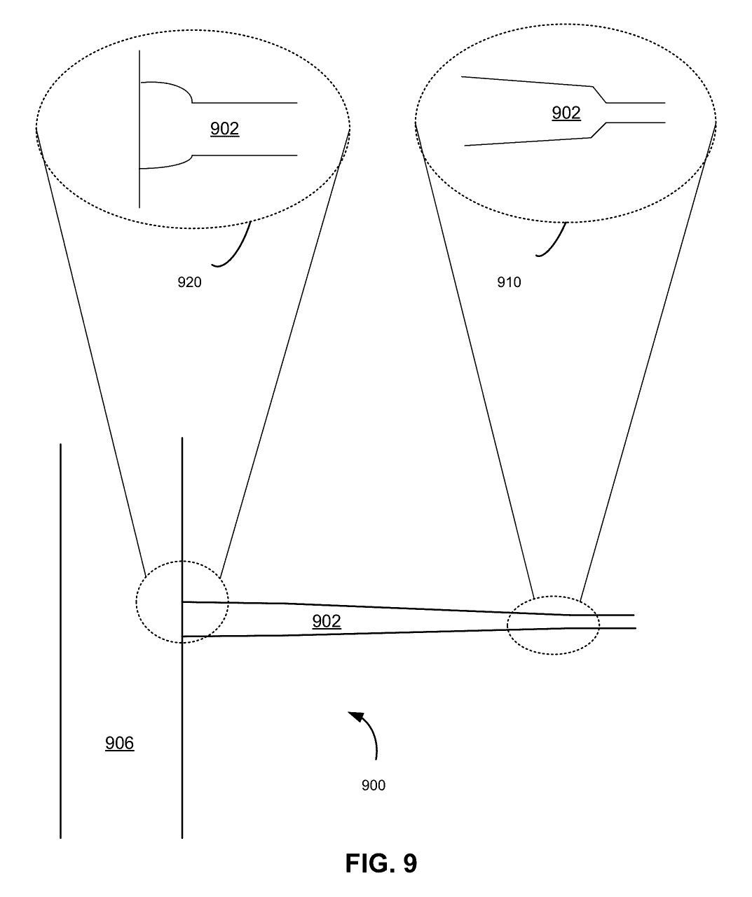

In the examples shown in FIGS. 3-8, sharp corners may be created within a variable width segment or at intersection of different segments of the finger lines with fixed and/or variable widths. These sharp corners may accumulate lateral stress that may cause metal breaking. In one embodiment, these sharp corners can be rounded or chamfered to further improve the adhesion of the metal lines and reduce the lateral stress. FIG. 9 shows an exemplary electroplated metallic grid on the surface of a photovoltaic structure, according to an embodiment of the present invention. As shown in FIG. 9, metallic grid 900 includes finger line 902 having chamfered or rounded corners near region 910 where a fixed width segment and a variable width segment of finger line 902 meet. Specifically, the detailed view of region 910 shows that chamfers can be created where the variable width segment connects to an end portion of finger line 902 close to the edge of the sub-grid to avoid creation of straight angles or sharp turns. In one embodiment, the intersection of finger line 902 and busbar 906 can also be rounded or chamfered. As shown in detailed views of FIG. 9, region 920 of finger line 902 can be rounded for better physical connection and improved height uniformity. In some embodiments, the radius of the arc can be between 0.01 mm and one-half of the finger spacing. Note that the finger spacing can be between 2 and 3 mm. Moreover, the chamfers may have different angles based on different parameters, such as a width differential between two segments of the finger line with a variable width.

Further, there may be several different designs for metallic grid of a photovoltaic structure using variable width finger lines. Depending on each pattern design, there may be different ranges of the variable width desired. In one embodiment, the variable width portion of the finger line can be approximately 10%-100% greater than other portions of the finger line. In another embodiment, the width of the finger line at or near an intersection of a busbar and the finger line can be much greater than 10%-100% range mentioned above. For example, the variable width of the finger line at the intersection point can be sufficiently wide to connect the finger line to the adjacent finger line. In some embodiments, the length of this variable width portion(s) can be from 1 mm up to an entire length of the finger line as shown in previous examples. Greater length of the widened finger line portion can result in better adhesion and more uniform thickness throughout the finger line and at intersection between the finger line and the busbar.

Although thicker finger lines may increase shading loss, such increase can be negligible in most cases. However, in cases that shading effect has to be minimized, different metallic grid patterns can be used. Moreover, the additional shading loss may also be offset by the additional current collected by these thicker finger lines, lower series resistance, and better long term reliability due to more robust finger lines.

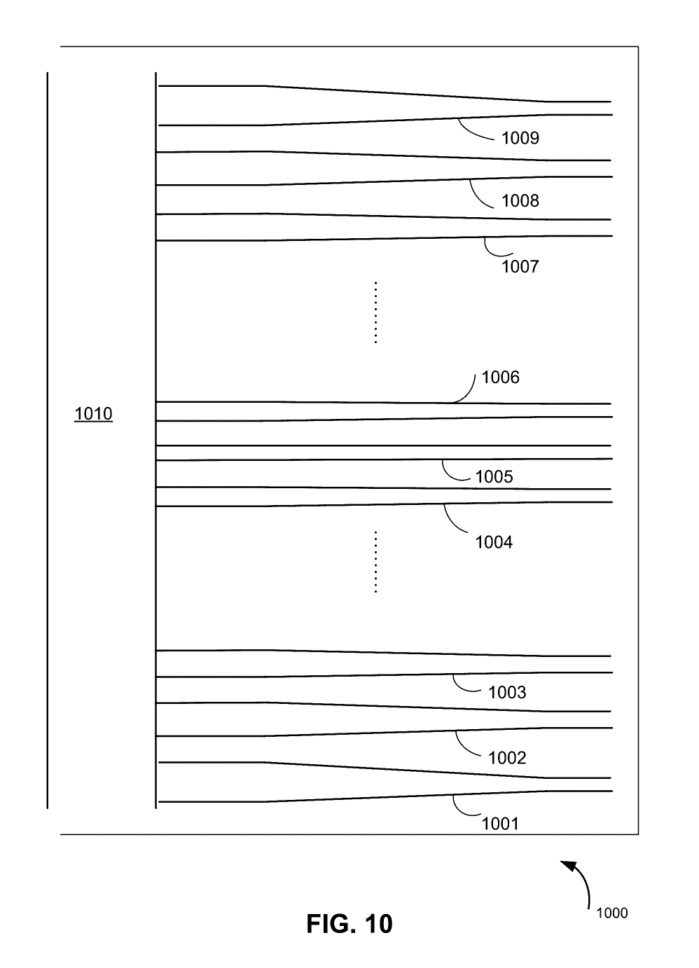

In some cases where shading effect is to be controlled and minimized, additional variable width finger line patterns can be used. These patterns not only minimize shading, but also maximize finger line strength to better cope with physical stress and external forces. In one embodiment, multiple variable width finger lines with different widths can be positioned in different areas of the metallized surface. FIG. 10 shows an exemplary electroplated metallic grid of a photovoltaic structure, according to an embodiment of the present invention. As shown in FIG. 10, metallic grid 1000 can include multiple finger lines each having variable widths. These finger lines can create a pattern based on the geometry of a wafer. As can be seen, finger lines 1001 and 1009 are located at two ends of the metallic grid close to the edges of the wafer. Because of their position, they may experience greater physical stress. Therefore, they may have a wider width to produce thicker finger lines compensating for the greater physical stress exerted on these finger lines. In contrast, finger lines located near the middle of the wafer, for example finger lines 1004-1006, may experience smaller amount of physical stress due to their location. Therefore, these finger lines may be narrower than finger lines 1001 and 1009. The resulting metallic grid can exhibit gradual transition from the sides of the metallic grid with thicker finger lines to the center of the wafer with thinner finger lines. This gradual transition is provided by positioning the thickest and widest finger lines at the edge of the wafer and the thinnest and mot narrow finger lines near the center of the wafer as shown in FIG. 10. The resulting pattern would produce a more reliable photovoltaic structure with reduced shading loss and higher efficiency.

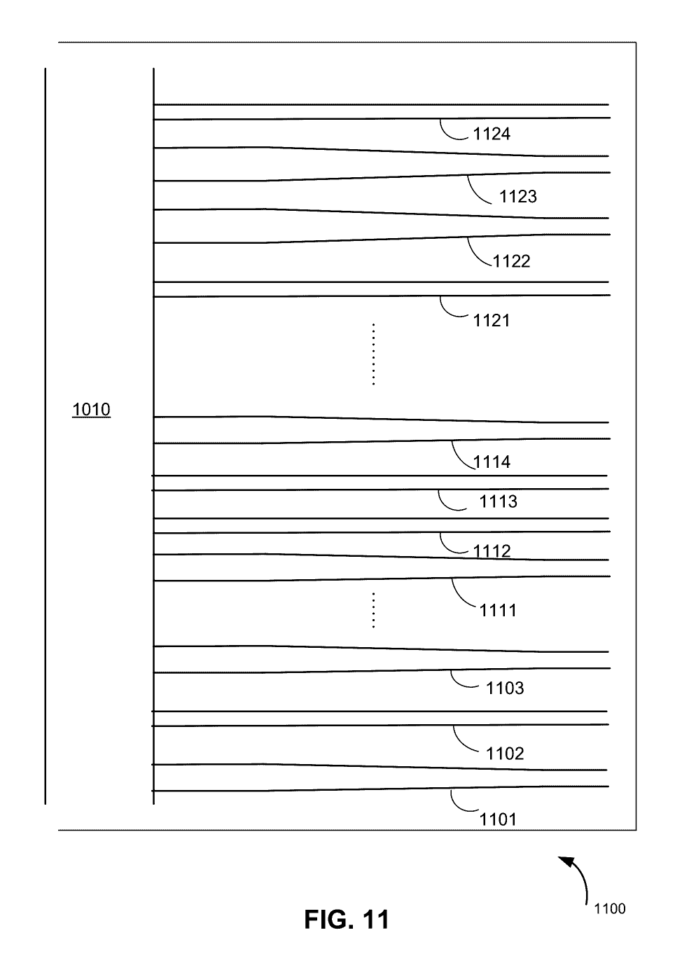

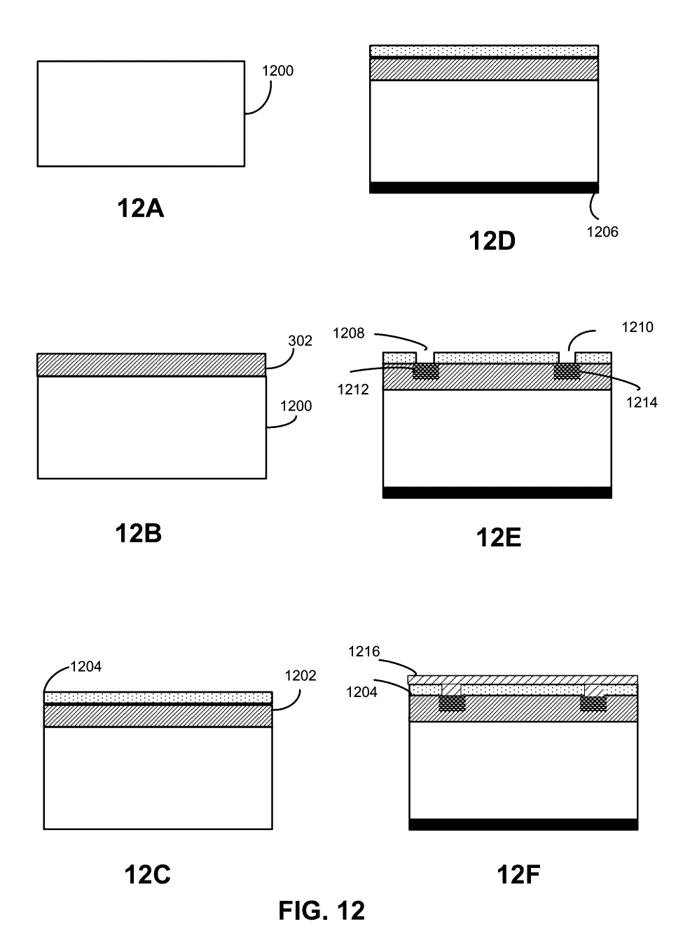

In another embodiment, variable width finger lines can be alternately placed throughout the metallic grid to further reduce the shading effect. FIG. 11 shows another exemplary electroplated metallic grid on a photovoltaic structure, according to an embodiment of the present invention. As shown in FIG. 11, variable width finger lines can be placed on the metallic grid using different configurations. In one embodiment, every other finger line of the metallic grid can have a variable width. For example, variable-width finger lines 1101 and 1103 can be separated by a fixed-width finger line 1102. In another embodiment, there may be one or more fixed-width finger lines between two variable-width finger lines. For example, fixed-width finger lines 1112 and 1113 can be between variable-width finger lines 1111 and 1114. In a further embodiment, two or more finger lines can be between two fixed-width finger lines. For example, variable-width finger lines 1122 and 1123 can be placed between fixed-width finger lines 1121 and 1124. Such configurations could potentially reduce shading loss while mitigating peeling of finger lines and loading effect in an electroplated metallic grid of a photovoltaic structure.

Note that the finger patterns shown in FIGS. 3-11 are merely examples, and they are not intended to be exhaustive or to limit the present invention to the finger patterns disclosed in these figures. Embodiments of the present invention can include any finger patterns that include variable width finger lines. Such patterns play important roles in mitigating the adverse effects facing the electroplated metallic grid since they help to divert current from some portions of finger lines, provide structural support, and result in more uniform electroplated metallic grid on a photovoltaic structure.

### Exemplary Fabrication Method I

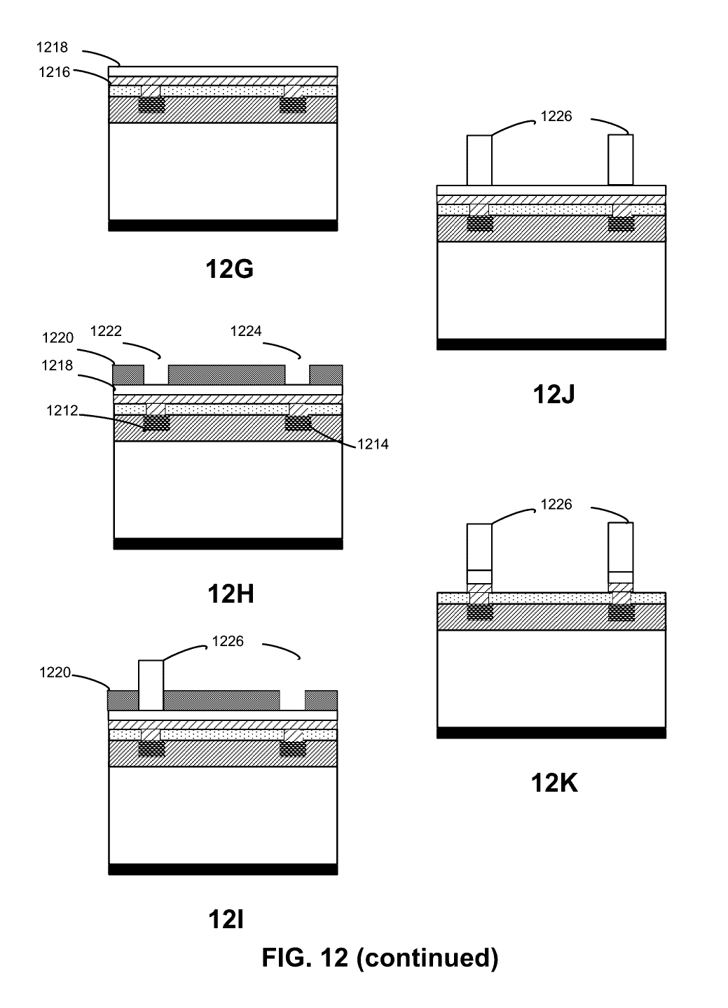

FIG. 12 shows an exemplary process of fabricating a photovoltaic structure, according to an embodiment of the present invention.

In operation 12A, a substrate 1200 is prepared. In one embodiment, substrate 1200 can be a crystalline-Si (c-Si) wafer. In a further embodiment, preparing c-Si substrate 1200 can include saw damage etch, which removes the damaged outer layer of Si, and surface texturing. The c-Si substrate 1200 can be lightly doped with either n-type or p-type dopants. In one embodiment, c-Si substrate 1200 can be lightly doped with p-type dopants. Note that in addition to c-Si, other materials (e.g., metallurgical-Si) can also be used to form substrate 1200.

In operation 12B, a doped emitter layer 1202 is formed on top of c-Si substrate 1200. Depending on the doping type of c-Si substrate 1200, emitter layer 1202 can be either n-type doped or p-type doped. In one embodiment, emitter layer 1202 is doped with n-type dopant. In a further embodiment, emitter layer 1202 is formed by diffusing phosphorous. Note that if phosphorus diffusion is used for forming emitter layer 1202, phosphosilicate glass (PSG) etch and edge isolation can be used. Other methods are also possible to form emitter layer 1202. For example, one can first form a poly Si layer on top of substrate 1200, and then diffuse dopants into the poly Si layer. The dopants can include either phosphorus or boron. Moreover, emitter layer 1202 can also be formed by depositing a doped amorphous Si (a-Si) layer on top of substrate 1200.

In operation 12C, an anti-reflection layer 1204 is formed on top of emitter layer 1202. In one embodiment, anti-reflection layer 1204 includes, but not limited to: silicon nitride (SiNₓ), silicon oxide (SiOₓ), titanium oxide (TiOₓ), aluminum oxide (Al₂O₃), and their combinations. In one embodiment, anti-reflection layer 1204 can include a layer of a transparent conducting oxide (TCO) material, such as indium tin oxide (ITO), aluminum zinc oxide (AZO), gallium zinc oxide (GZO), tungsten doped indium oxide (IWO), and their combinations.

In operation 12D, back-side electrode 1206 is formed on the back side of Si substrate 1200. In one embodiment, forming back-side electrode 1206 includes printing a full Al layer and subsequent alloying through firing. In one embodiment, forming back-side electrode 1206 can include printing an Ag/Al grid and subsequent furnace firing. In a further embodiment, forming back-side electrode 1206 can include electroplating the printed Ag/Al grid using one or more of a Cu layer, an Ag layer, and a Sn layer.

In operation 12E, a number of contact windows, including windows 1208 and 1210, can be formed in anti-reflection layer 1204. In one embodiment, heavily doped regions, such as regions 1212 and 1214 can be formed in emitter layer 1202, directly beneath contact windows 1208 and 1210, respectively. In a further embodiment, contact windows 1208 and 1210 and heavily doped regions 1212 and 1214 are formed by spraying phosphorous on anti-reflection layer 1204, followed by a laser-groove local-diffusion process. Note that operation 12E is optional, and can be performed when anti-reflection layer 1204 is electrically insulating. If anti-reflection layer 1204 is electrically conducting (e.g., when anti-reflection layer 1204 is formed using TCO materials), there is no need to form the contact windows.

In operation 12F, a metal adhesive layer 1216 is formed on anti-reflection layer 1204. In one embodiment, materials used to form adhesive layer 1216 include, but are not limited to: Ti, titanium nitride (TiNₓ), titanium tungsten (TiWₓ), titanium silicide (TiSiₓ), titanium silicon nitride (TiSiN), Ta, tantalum nitride (TaNₓ), tantalum silicon nitride (TaSiNₓ), nickel vanadium (NiV), tungsten nitride (WNₓ), Cu, Al, Co, W, Cr, Mo, Ni, and their combinations. In a further embodiment, metal adhesive layer 1216 is formed using a physical vapor deposition (PVD) technique, such as sputtering or evaporation. The thickness of adhesive layer 1216 can range from a few nanometers up to 100 nm. Note that Ti and its alloys tend to form very good adhesion with Si material, and they can form good ohmic contact with heavily doped regions 1212 and 1214. Forming metal adhesive layer 1214 on top of anti-reflection layer 1204 prior to the electroplating process can provide better adhesion to anti-reflection layer 1204 of the subsequently formed layers.

In operation 12G, a metal seed layer 1218 can be formed on adhesive layer 1216. Metal seed layer 1218 can include Cu or Ag. The thickness of metal seed layer 1218 can be between 12 nm and 500 nm. In one embodiment, metal seed layer 1218 has a thickness of 100 nm. Like metal adhesive layer 1216, metal seed layer 1218 can be formed using a PVD technique. In one embodiment, the metal used to form metal seed layer 1218 is the same metal that used to form the first layer of the electroplated metal. The metal seed layer provides better adhesion of the subsequently plated metal layer. For example, Cu plated on Cu often has better adhesion than Cu plated on to other materials.

In operation 12H, a patterned masking layer 1220 is deposited on top of metal seed layer 1218. The openings of masking layer 1220, such as openings 1222 and 1224, correspond to the locations of contact windows 1208 and 1210, and thus are located above heavily doped regions 1212 and 1214. Note that openings 1222 and 1224 are slightly larger than contact windows 1208 and 1210. Masking layer 1220 can include a patterned photoresist layer, which can be formed using a photolithography technique. In one embodiment, the photoresist layer is formed by screen-printing photoresist on top of the wafer. The photoresist can then be cured. A mask can be laid on the photoresist, and the wafer is exposed to UV light. After the UV exposure, the mask is removed, and the photoresist is developed in a photoresist developer. Openings 1222 and 1224 are formed after developing. The photoresist can also be applied by spraying, dip coating, or curtain coating. Dry film photoresist can also be used. Alternatively, masking layer 1220 can include a layer of patterned silicon oxide (SiO₂). In one embodiment, masking layer 1220 is formed by first depositing a layer of SiO₂ using a low-temperature plasma-enhanced chemical-vapor-deposition (PECVD) technique. In a further embodiment, masking layer 1220 can be formed by dip-coating the front surface of the wafer using silica slurry, followed by screen-printing an etchant that includes hydrofluoric acid or fluorides. Other masking materials are also possible, as long as the masking material is electrically insulating.

Note that masking layer 1220 defines the pattern of the front metallic grid because, during the subsequent electroplating, metal materials can only be deposited on regions above the openings, such as openings 1222 and 1224, defined by masking layer 1220. To ensure better thickness uniformity and better adhesion, the pattern defined by masking layer 1220 can include variable width finger lines that are formed to have varying thickness along some finger lines. Exemplary patterns formed by masking layer 1220 include patterns shown in FIGS. 3-11.

In operation 12I, one or more layers of metal are deposited at the openings of masking layer 1220 to form a front-side metallic grid 1226. Front-side metallic grid 1226 can be formed using an electroplating technique, which can include electrodeposition, light-induced plating, and/or electroless deposition. In one embodiment, metal seed layer 1218 and/or adhesive layer 1216 are coupled to the cathode of the plating power supply, which can be a direct current (DC) power supply, via an electrode. Metal seed layer 1218 and masking layer 1220, which includes the openings, are submerged in an electrolyte solution which permits the flow of electricity. Note that, because masking layer 1220 is electrically insulating, metals will be selectively deposited into the openings, thus, forming a metallic grid with a pattern corresponding to the one defined by those openings. Depending on the material forming metal seed layer 1218, front-side metallic grid 1226 can be formed using Cu or Ag. For example, if metal seed layer 1218 is formed using Cu, front-side metallic grid 1226 is also formed using Cu. In addition, front-side metallic grid 1226 can include a multilayer structure, such as a Cu/Sn bi-layer structure, or a Cu/Ag bi-layer structure. The Sn or Ag top layer is deposited to assist a subsequent soldering process. When depositing Cu, a Cu plate is used at the anode, and the photovoltaic structure is submerged in the electrolyte suitable for Cu plating. The current used for Cu plating is between 0.1 ampere and 2 amperes for a wafer with a dimension of 125 mm×125 mm, and the thickness of the Cu layer is approximately tens of microns. In one embodiment, the thickness of the electroplated metal layer is between 30 μm and 50 μm.

In operation 12J, masking layer 1220 is removed.

In operation 12K, portions of adhesive layer 1216 and metal seed layer 1218 that are originally covered by masking layer 1220 are etched away, leaving only the portions that are beneath front-side metallic grid 1226. In one embodiment, wet chemical etching process is used. Note that, because front-side metallic grid 1226 is much thicker (by several magnitudes) than adhesive layer 1216 and metal seed layer 1218, the etching has a negligible effect on front-side metallic grid 1226. In one embodiment, the thickness of the resulting metallic grid can range from 30 μm to 50 μm. The width of the finger strips can be between 10 μm to 200 μm, and the width of the busbars can be between 0.5 to 2 mm. Moreover, the spacing between the finger strips can be between 2 mm and 3 mm.

During fabrication, after the formation of the metal adhesive layer and the seed metal layer, it is also possible to form a patterned masking layer that covers areas that correspond to the locations of contact windows and the heavily doped regions, and etch away portions of the metal adhesive layer and the metal seed layer that are not covered by the patterned masking layer. In one embodiment, the leftover portions of the metal adhesive layer and the metal seed layer form a pattern that is similar to the ones shown in FIGS. 3-11. Once the patterned masking layer is removed, one or more layers of metals can be electroplated to the surface of the photovoltaic structure. On the photovoltaic structure surface, only the locations of the leftover portions of the metal seed layer are electrically conductive, a plating process can selectively deposit metals on top of the leftover portions of metal seed layer.

In the example shown in FIG. 12, the back-side electrode is formed using a conventional printing technique (operation 12D). In practice, the back-side electrode can also be formed by electroplating one or more metal layers on the backside of the photovoltaic structure. In one embodiment, the back-side electrode can be formed using operations that are similar to operations 12F-12K, which include forming a metal adhesive layer, a metal seed layer, and a patterned masking layer on the backside of the substrate. Note that the patterned masking layer on the backside defines the pattern of the back-side metallic grid. In one embodiment, the back-side metallic grid includes variable width finger strips. In a further embodiment, the back-side metallic grid may include exemplary patterns shown in FIGS. 3-11.

### Exemplary Fabrication Method II

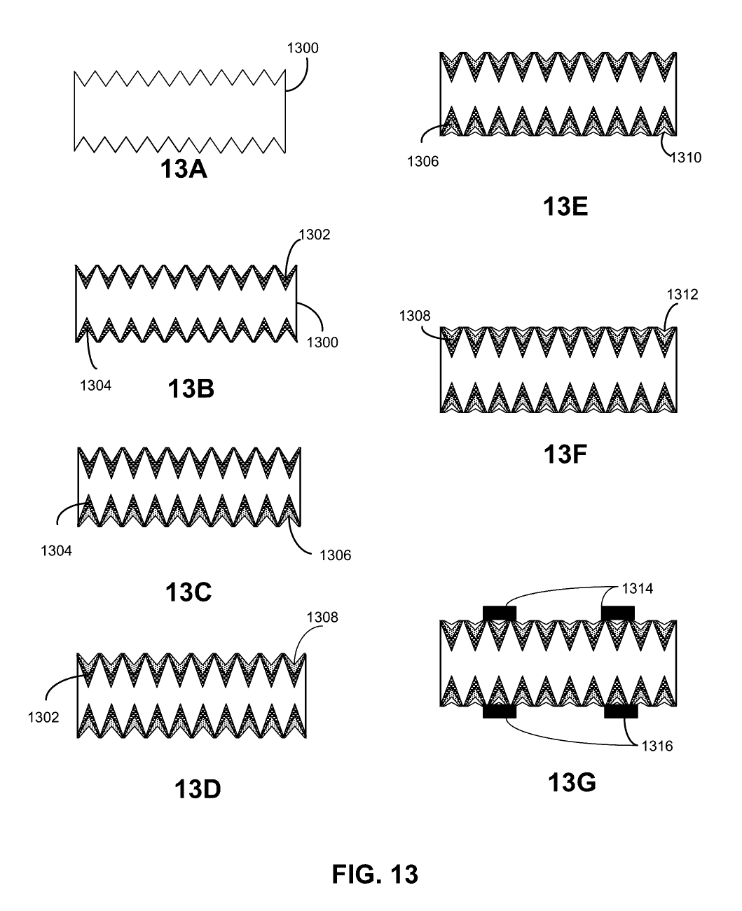

FIG. 13 shows another exemplary process of fabricating a back junction photovoltaic structure with tunneling oxide, according to an embodiment of the present invention.

In operation 13A, a substrate 1300 is prepared. Either n- or p-type doped high-quality solar-grade silicon (SG-Si) wafers can be used to build the back junction solar cell. In one embodiment, an n-type doped SG-Si wafer is selected. The thickness of SG-Si substrate 1300 can range between 80 and 200 μm. In one embodiment, the thickness of SG-Si substrate 1300 ranges between 90 and 120 μm. The resistivity of SG-Si substrate 1300 can range between 1 Ohm-cm and 10 Ohm-cm. In one embodiment, SG-Si substrate 200 has a resistivity between 1 Ohm-cm and 2 Ohm-cm. The preparation operation can include typical saw damage etching that removes approximately 10 μm of silicon and surface texturing. The surface texture can have various patterns, including but not limited to: hexagonal-pyramid, inverted pyramid, cylinder, cone, ring, and other irregular shapes. In one embodiment, the surface texturing operation can result in a random pyramid textured surface. Afterwards, SG-Si 200 substrate goes through extensive surface cleaning.

In operation 13B, a thin layer of high-quality (with D₁ less than 1×10¹¹/cm²) dielectric material can be deposited on the front and back surfaces of SG-Si substrate 1300 to form front and back passivation/tunneling layers 1302 and 1304, respectively. In one embodiment, only the back surface of SG-Si substrate 1300 is deposited with a thin layer of dielectric material. Various types of dielectric materials can be used to form the passivation/tunneling layers, including, but not limited to: silicon oxide (SiOₓ), hydrogenerated SiOₓ, silicon nitride (SiNₓ), hydrogenerated SiNₓ, aluminum oxide (AlOₓ), silicon oxynitride (SiON), and hydrogenerated SiON. In addition, various deposition techniques can be used to deposit the passivation/tunneling layers, including, but not limited to: thermal oxidation, atomic layer deposition, wet or steam oxidation, low-pressure radical oxidation, plasma-enhanced chemical-vapor deposition (PECVD), etc. The thickness of tunneling/passivation layers 1302 and 1304 can be between 1 and 50 angstroms. In one embodiment, the thickness of tunneling/passivation layers 1302 and 1304 is between 1 and 15 angstroms. Note that the well-controlled thickness of the tunneling/passivation layers can ensure good tunneling and passivation effects.

In operation 13C, a layer of hydrogenerated, graded-doping a-Si having a doping type opposite to that of substrate 200 can be deposited on the surface of back passivation/tunneling layer 1304 to form emitter layer 1306. As a result, emitter layer 1306 can be positioned on the backside of the solar cell facing away from the incident sunlight. Note that, if SG-Si substrate 1300 is n-type doped, then emitter layer 206 is p-type doped, and vice versa. In one embodiment, emitter layer 206 can be p-type doped using boron as dopant. SG-Si substrate 1300, back passivation/tunneling layer 1304, and emitter layer 1306 can form the hetero-tunneling back junction. The thickness of emitter layer 1306 can be between 1 and 20 nm. Note that an optimally doped (with doping concentration varying between 1×10¹⁵/cm³ and 5×10²⁰/cm³) and sufficiently thick (at least between 3 nm and 20 nm) emitter layer can be used to ensure a good ohmic contact and a large built-in potential. In one embodiment, the region within emitter layer 1306 that is adjacent to front passivation/tunneling layer 1302 can have a lower doping concentration, and the region that is away from front passivation/tunneling layer 1302 has a higher doping concentration. The lower doping concentration can ensure minimum defect density at the interface between back passivation/tunneling layer 1304 and emitter layer 1306, and the higher concentration on the other side may prevent emitter layer depletion. The work function of emitter layer 1306 can be tuned to better match that of a subsequently deposited back transparent conductive oxide (TCO) layer to enable higher fill factor. In addition to a-Si, it is also possible to use other material, including but not limited to: one or more wide-bandgap semiconductor materials and polycrystalline Si, to form emitter layer 1306.

In operation 13D, a layer of hydrogenerated, graded-doping a-Si having a doping type same as that of substrate 1300 can be deposited on the surface of front passivation/tunneling layers 1302 to form front surface field (FSF) layer 1308. Note that, if SG-Si substrate 1300 is n-type doped, then FSF layer 1308 is also n-type doped, and vise versa. In one embodiment, FSF layer 1308 can be n-type doped using phosphorous as dopant. SG-Si substrate 1300, front passivation/tunneling layer 1302, and FSF layer 1308 form the front surface high-low homogenous junction that can effectively passivates the front surface. In one embodiment, the thickness of FSF layer 1308 can be between 1 and 30 nm. The doping concentration of FSF layer 1308 can vary from 1×10¹⁵/cm³ to 5×10²⁰/cm³. In addition to a-Si, it is also possible to use other material, including but not limited to: wide-bandgap semiconductor materials and polycrystalline Si, to form FSF layer 1308.

In operation 13E, a layer of TCO material can be deposited on the surface of emitter layer 1306 to form a back-side conductive anti-reflection layer 210, which ensures a good ohmic contact. Examples of TCO include, but are not limited to: indium-tin-oxide (ITO), indium oxide (InO), indium-zinc-oxide (IZO), tungsten-doped indium-oxide (IWO), tin-oxide (SnOₓ), aluminum doped zinc-oxide (ZnO:Al or AZO), Zn—In—O (ZIO), gallium doped zinc-oxide (ZnO:Ga), and other large bandgap transparent conducting oxide materials. The work function of back-side TCO layer 1310 can be tuned to better match that of emitter layer 1306.

In operation 13F, front-side TCO layer 1312 can be formed on the surface of FSF layer 1308. Front-side TCO layer 1312 can form a good anti-reflection coating to optimize transmission of sunlight into the solar cell.

In operation 13G, front-side electrode 1314 and back-side electrode 1316 can be formed on the surfaces of TCO layers 1312 and 1310, respectively. In one embodiment, front-side electrode 1314 and back-side electrode 1316 can include Ag finger grids, which can be formed using various techniques, including, but not limited to: screen printing of Ag paste, inkjet or aerosol printing of Ag ink, and evaporation. In a further embodiment, front-side electrode 1314 and/or back-side electrode 1316 can include Cu grid formed using various techniques, including, but not limited to: electroless plating, electro plating, sputtering, and evaporation. Note that the electrodes on both sides can be formed using various patterns with variable width finger lines. In a further embodiment, the metallic grids of both sides may include exemplary patterns shown in FIGS. 3-11.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

The methods and processes described in the detailed description section can be embodied as code and/or data, which can be stored in a computer-readable storage medium as described above. When a computer system reads and executes the code and/or data stored on the computer-readable storage medium, the computer system can perform the methods and processes embodied as data structures and code and stored within the computer-readable storage medium.

The foregoing descriptions of embodiments of the invention have been presented for purposes of illustration and description only. They are not intended to be exhaustive or to limit the invention to the forms disclosed. Accordingly, many modifications and variations may be apparent to practitioners skilled in the art. Additionally, the above disclosure is not intended to limit the invention. The scope of the invention is defined by the appended claims.

What is claimed is:

1. A solar cell comprising:
a photovoltaic structure; and
an electroplated metallic grid positioned on a side of the photovoltaic structure, wherein the metallic grid includes a plurality of finger lines, wherein at least one of the plurality of finger lines has a first segment with a variable height.

2. The solar cell of claim 1, wherein the variable height of the first segment varies substantially linearly with respect to a direction along the finger line.

3. The solar cell of claim 1, wherein the variable height of the first segment varies substantially non-linearly with respect to a direction along the finger line.

4. The solar cell of claim 1, wherein the first segment includes a plurality of smaller segments each having a fixed height with a different fixed height value from adjacent smaller segments.

5. The solar cell claim 1, wherein the at least one of the plurality of finger lines includes a second segment with a variable height.

6. The solar cell of claim 5, wherein the second segment of the finger line is rounded or chamfered.

7. The solar cell of claim 5, wherein the height of the second segment varies substantially linearly with respect to a direction along the finger line.

8. The solar cell of claim 5, wherein the height of the second segment varies substantially non-linearly with respect to a direction along the finger line.

9. The solar cell of claim 5, wherein the second segment includes a plurality of smaller segments each having a fixed width with a different fixed height value from adjacent smaller segments.

10. The solar cell of claim 5, wherein the second segment has a concave shape, convex shape, or a combination thereof.

11. The Solar cell of claim 1, wherein the metallic grid further includes at least one busbar connected to the second segment of the finger line.

12-20. (canceled)
